(19) United States
(12) Patent Application Publication
(10) Pub. No.: US 2013/0027849 A1
(43) Pub. Date: Jan. 31, 2013

(54) PRESSURIZED WATERPROOF CASE FOR ELECTRONIC DEVICE

(71) Applicant: MICHAEL BERUMEN, THUWAL (SA)

(72) Inventor: MICHAEL BERUMEN, THUWAL (SA)

(73) Assignee: KING ABDULLAH UNIVERSITY OF SCIENCE AND TECHNOLOGY, THUWAL (SA)

(21) Appl. No.: 13/193,295

(22) Filed: Jul. 28, 2011

(51) Int. Cl. H05K 5/00; H05K 13/00

(52) U.S. Cl. 361/679.01; 29/592.1

(57) ABSTRACT

The pressurized waterproof case for an electronic device is particularly adapted for the waterproof containment and operation of a touch-screen computer or the like therein at some appreciable water depth. The case may be formed as an enclosure having an open top panel or face covered by a flexible, transparent membrane or the like for the operation of the touch-screen device within the case. A pressurizing system is provided for the case to pressurize the case and the electronic device therein to slightly greater than ambient in order to prevent the external water pressure from bearing against the transparent membrane and pressing it against the touch screen, thereby precluding operation of the touch screen device within the case. The pressurizing system may be a small gas cartridge (e.g., CO₂), or may be provided from an external source, such as the diver's breathing air. A pressure relief valve is also provided.

### BACKGROUND OF THE INVENTION

1. Field of the Invention

The present invention relates generally to cases, containers, and the like, and particularly to a pressurized waterproof case for an electronic device, and particularly to a case that permits the use of a touch-screen electronic device contained therein while underwater, e.g., while scuba diving.

2. Description of the Related Art

Scuba divers often find it necessary to take notes or to record information while underwater. Examples include training where an instructor may write notes or messages for students (or students may communicate with their instructor in the same manner), and commercial divers who need to communicate with other divers during a working dive. One area in which the recording of information underwater is absolutely critical is in the field of underwater research. Marine scientists and researchers must often take notes, label samples that have been collected, fill in data sheets, and record other information. This is conventionally done by using a standard pencil on waterproof paper, which has been found to be workable in years of practice.

While this means of underwater communication and information collecting may be acceptable for transient information that is not of permanent value, it leaves much to be desired as a method of recording information permanently. When the information is to be made as a permanent record, the researcher or scientist typically makes notes at the site using waterproof paper and pencil, as noted further above. These rough notes are later transcribed into a more permanent record, and/or recorded in a computer database or other suitable program. Aside from the additional time that this requires, one problem that can occur at this point is the entry of an error or errors when transcribing from the original notes to the more permanent record. Even if the original notes were absolutely accurate, it is still very easy to introduce some error(s) inadvertently during the transcription, particularly if a large amount of data is being transcribed.

As a result, scientists, researchers, and others who have occasion to work underwater have long desired some means of making a permanent record during the initial step of recording data underwater. The relatively recent development of various forms of tablet computers, and particularly touch-screen devices, such as the Apple iPad®, has enabled persons working on land to accomplish such note taking and data entry directly into such devices, thereby eliminating the step of hand-written notes and the like. However, such computer devices cannot be used underwater without suitable protection from the elements.

One solution that has been attempted in the past is merely to insert the computer or electronic device into a flexible clear plastic bag or the like that can be sealed to prevent the entry of water into the bag and electronic device. This may be an acceptable solution for such devices for protecting them from the elements, e.g., on the beach or ski slope, or perhaps at a dusty construction site or in inclement weather, but it is unworkable for a touch-screen device to be used underwater. Water pressure at depths routinely encountered by scuba divers and snorkelers bears against the protective plastic bag or container, and in turn bears directly over the entire surface of the computer, including the touch screen. This results in the screen being unable to distinguish a localized touch for the purpose of data entry or the like, rendering the touch-screen device useless as a tool in an underwater environment at any appreciable depth, even when the electronic circuits are protected from the water.

Thus, a pressurized waterproof case for an electronic device solving the aforementioned problems is desired.

### SUMMARY OF THE INVENTION

The pressurized waterproof case for an electronic device is adapted particularly for the protection and use of a touch-screen tablet computer or the like in the underwater environment. The case is formed of a series of rigid panels and a transparent, flexible membrane or sheet forming one side or surface of the device. Alternatively, the rigid portions of the case may be formed as a unitary, monolithic structure by injection molding, blow molding, or other plastics manufacturing processes, and the transparent membrane or sheet forming one side or surface of the device may be joined and sealed thereto by adhesive, ultrasonic welding, or other joining processes known in the art. The rigid panels or unitary case may be transparent, translucent, or opaque. A removable hatch, cover, or the like may be provided in one of the rigid panels or case, or may comprise one of the rigid panels. The hatch or cover includes sealing means to assure that water cannot enter the case. The hatch or cover is of sufficient size to allow a touch-screen computer or similar device to be installed within and removed from the case as desired.

The case is preferably fluid-tight. A source of pressurized air or other gas is provided to pressurize the interior of the case slightly higher than ambient pressure. This assures that the flexible panel or membrane overlying the touch screen is not pressed against the touch screen due to external water pressure higher than the pressure within the case. Such a condition would render the touch screen computer unusable due to the uniform pressure developed over the entire screen as the higher external pressure pressed against the flexible membrane overlying the screen, causing the flexible membrane to make contact with the screen. The slightly higher than ambient pressure provided within the ease permeates the electronic device within the case to equalize the pressure internal and external to the electronic device within the case, and specifically separates the flexible membrane from the surface of the touch screen. Thus, the diver or other party using the device may apply touch pressures to various areas of the touch screen through the flexible membrane to operate the device conventionally while at some depth underwater.

The source of pressurized gas for the device may comprise a small gas cartridge (e.g., CO₂, etc.) removably connected to the case through an on/off or regulator valve, or may comprise a line from an external source of pressure, e.g., the diver's breathing air supply, and conventional and appropriate pressure regulation and safety shutoff means may also be provided. An overpressure relief valve may also be provided in the case.

These and other features of the present invention will become readily apparent upon further review of the following specification and drawings.

### BRIEF DESCRIPTION OF THE DRAWINGS

FIG. 1 is an environmental, perspective view of a pressurized waterproof case for an electronic device according to the present invention, illustrating the case in use in an underwater environment.

FIG. 2 is a perspective view of an exemplary embodiment of a pressurized waterproof case for an electronic device according to the present invention, shown with the case closed and with a touch-screen electronic device contained therein.

FIG. 3 is a partially exploded perspective view of an alternative embodiment of a pressurized waterproof case for an electronic device according to the present invention, showing the end panel removed for accessing the interior of the device and showing an alternative source of pressurization.

Similar reference characters denote corresponding features consistently throughout the attached drawings.

### DETAILED DESCRIPTION OF THE PREFERRED EMBODIMENTS

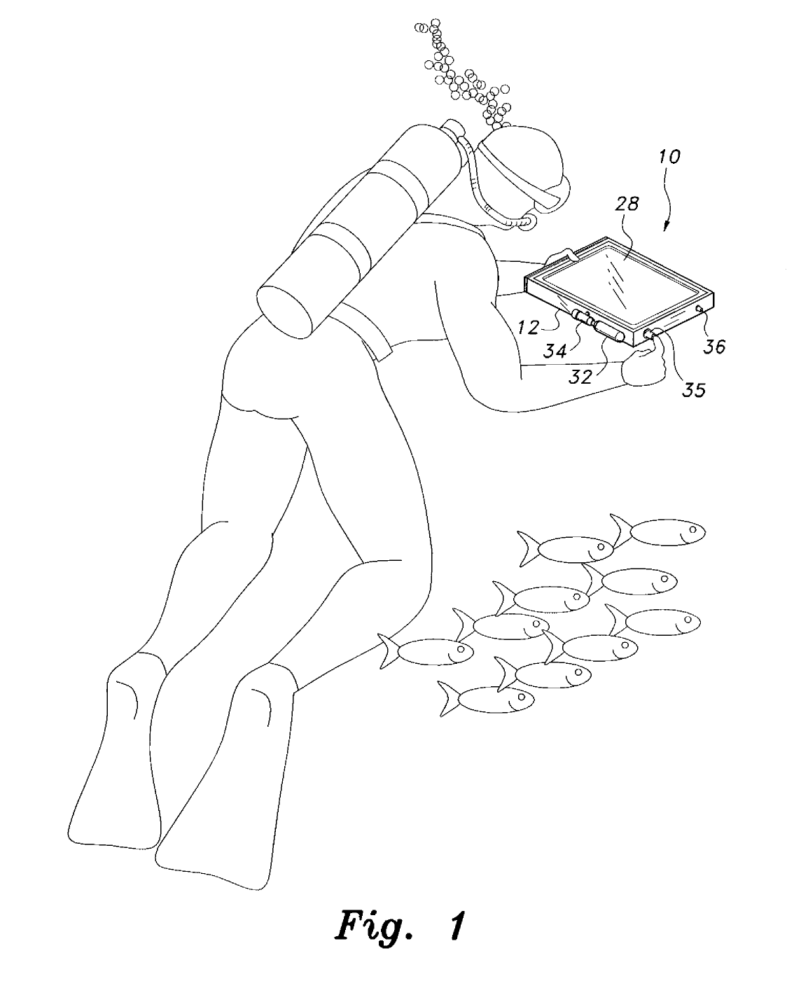

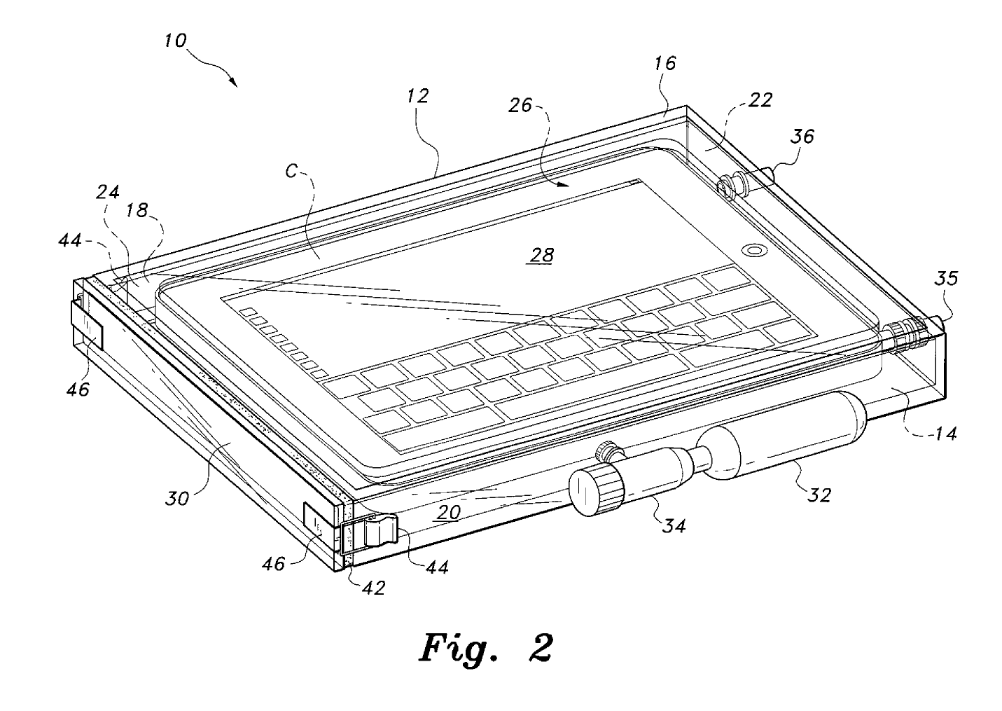

The pressurized waterproof case for an electronic device enables a diver to protect a touch-screen computer device while underwater, and enables the diver to use the device as desired in the underwater environment. FIG. 1 of the drawings provides an environmental view of the pressurized waterproof case for an electronic device 10 in use during a dive, with reference being made as well to the perspective view of the exemplary embodiment of the case 10 in FIG. 2 for a more detailed view.

The case 10 comprises a relatively thin, flat housing 12 adapted for the waterproof containment of a comparably configured touch-screen tablet computer C or the like, e.g., an iPad® or similar device. The housing 12, in turn, is formed of a rigid back panel 14, a rigid front frame or panel 16 opposite the back panel 14, mutually opposed rigid side panels 18, 20 extending between the back panel 14 and the front frame 16 to provide a space therebetween for the computer C, and an end panel 22. The various panels 14 through 22 are all imperviously sealed to one another by suitable conventional means (e.g., a cement or adhesive forming a watertight and fluid-tight seal), and define an enclosure or internal volume 24 adapted for the placement of a touch-screen electronic device, such as the tablet computer C, therein. The various panels 14 through 22 may be formed of any suitably waterproof material of sufficient strength, and the panels 14 through 22 may be transparent, translucent, or opaque, as only the screen of the computer device C need be observed by the user of the case 10. For example, clear or translucent acrylic sheet material may be used to form the panels 14 through 22, although polycarbonate or other suitable material may be used. The use of plastics provides for the transmission of radio frequencies therethrough, allowing the computer C contained within the case 10 to communicate with other devices through conventional means (e.g., Bluetooth®) often provided with such computers. Alternatively, the housing 12 may be formed as a unitary, monolithic structure by injection molding, blow molding, or other plastics manufacturing processes, or may be formed from composites or other non-corrosive materials by any conventionally known process.

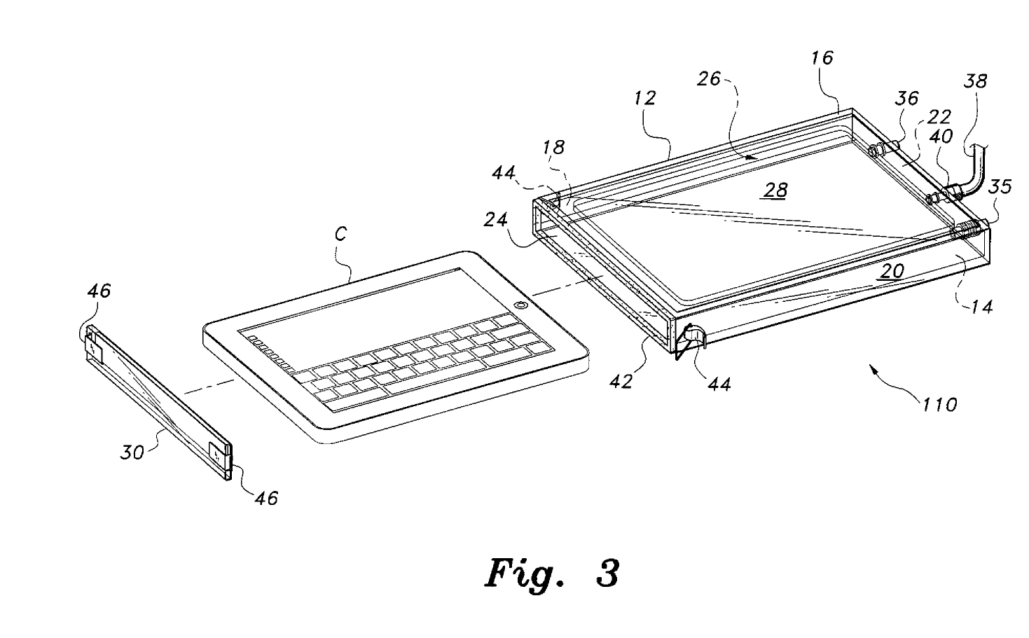

The front frame 16 includes a large opening 26 therethrough. The opening 26 is covered and sealed by a thin, flexible, transparent touch-screen operation membrane or panel 28. The flexible and transparent touch-screen panel 28 enables the user of the case 10 to apply pressure to any point on the membrane or panel 28 to contact the underlying portion of the touch-screen of the computer C, thereby operating the computer in its sealed case 10. A removable hatch or cover 30 may be provided opposite the fixed end panel 22, allowing the user of the case 10 to install and remove the computer C. Details of the removable hatch 30 are illustrated in FIG. 3 and discussed further below.

It will be recognized that submersion of the sealed case 10 to any appreciable depth will result in the water pressure exerting a force upon the flexible panel or membrane 28, causing it to deflect inwardly into the internal volume 24 within the case 10. The panel or membrane 28 would, in turn, press upon the screen of a touch-screen computer device C sealed therein, the uniform pressure developed over the entire screen surface obviating the ability to apply any meaningful tactile input to the screen of the computer C, even though the computer is sealed from the water outside the case 10.

Accordingly, the case 10 is pressurized internally to counteract the external pressure developed by the water at the operating depth of the case. The case 10 may include a source of pressurized gas disposed upon one of the panels, e.g., the end panel 22, although the pressurized gas source may communicate with any of the panels 14 through 22 or the removable hatch 30 as desired. In the example of FIGS. 1 and 2, the pressurized gas source is a small cartridge 32 of carbon dioxide (CO₂) of the type conventionally used for the inflation of life preservers and other inflatable devices. A regulator valve 34 is attached to the housing 12 and communicates with the internal volume 24 of the case 10, the cartridge 32 being removably attached to the regulator valve 34.

The regulator valve 34 is adjusted to provide an internal pressure within the case 10 that is slightly higher than the ambient water pressure at the working depth of the case. The user of the case 10 can easily adjust the pressure by means of the regulator valve 34 while observing the shape of the flexible panel or membrane 28. If too little pressure is provided to the internal volume 24 of the case 10, the panel 28 will be deflected inward onto the screen of the computer C. If too great a pressure is provided, the panel or membrane 28 will be deflected outward according to the pressure differential between the internal volume 24 of the case 10 and the external water pressure. Thus, the user of the case 10 need only adjust the regulator periodically to cause the flexible panel or membrane 28 to deflect slightly outward from the case 10. The slightly greater pressure within the case 10 not only provides for proper operation of the touch-screen computer C within the case 10, but also prevents the inflow of water into the case 10 in the event of any slight leakage at any point.

As the computer C is not pneumatically sealed, the gas pressure developed within the case 10 with the computer C sealed therein will result in the pressure within the computer C being equal to the pressure within the case 10, but outside of the computer C. Thus, no net pressure is developed on either side of the touch screen of the computer C. However, the slightly greater pressure within the case 10 relative to the external water pressure results in the flexible membrane or panel 28 being deflected away from the touch screen of the computer C contained within the case 10. Thus, a diver using the pressurized waterproof case 10 with the computer C sealed therein need only apply localized fingertip pressure to the flexible panel or membrane 28 to deflect it inward to the screen of the computer C, thereby controlling the computer C by means of its touch screen.

The case 10 may also include a pressure relief valve 36 disposed upon one of the panels of the case 10 that communicates with the internal volume 24 of the case. Such a pressure relief valve 36 is illustrated in FIGS. 1 through 3 extending from the end panel 22, but the valve 36 may be installed in any of the panels comprising the housing 12 of the case 10. The pressure relief valve 36 is a one-way check valve that opens to release gas when gas pressure inside the case 10 is greater than external pressure applied by water, but precludes the inflow of water into the case 10 should the external pressure be greater than the pressure within the case 10 at any point. The pressure relief valve 36 is set to allow only a relatively small differential pressure between the interior of the case 10 and the external pressure in order to preclude excessive distension of the flexible panel or membrane 28.

FIG. 3 of the drawings illustrates an alternative embodiment of the pressurized waterproof case, designated as case 110. The case 110 of FIG. 3 is formed of the same panel components as the case 10 of FIGS. 1 and 2, i.e., panels 14 through 22, and has the opening 26 in the front frame or panel 16 sealed by the flexible panel or membrane 28. The only difference between the case 10 of FIGS. 1 and 2 and the case 110 of FIG. 3 is the source of pressurized gas used to provide gas pressure to the internal volume 24 of the case 110. An external line 38 is removably connected to a fitting 40 of the end panel 22 of the case 110 of FIG. 3 to deliver air or other gas to the case 110. A conventional manually activated button or other control may be provided to allow the user to add pressure to the case 110 as desired. The source of the gas may be the diver's breathing air, as provided by a pressure regulator to provide the desired pressure to the case 110 and a shutoff valve at the diver's air tank for use in the event of excessive airflow to the case 110. Such regulators and shutoff valves are conventional, and accordingly are not illustrated. Other sources of pressurized gas for the case 10 may be provided as desired, e.g., a separate, remotely disposed gas cylinder (air, CO₂, etc.), carried by the diver.

FIG. 3 also provides an illustration of the removable hatch 30 for the cases 10 and 110. The hatch 30 and its mechanism are identical for the two cases 10 and 110. The hatch 30 may be formed of material identical to or dissimilar to the materials used to form the remainder of the case 10, so long as it is rigid. A resilient waterproof seal 42, e.g., an O-ring, resilient flange, etc., is installed about the open end or edge of the case 10, the rigid hatch 30 clamping tightly against the resilient seal 42 to seal the computer C within the case 10 and to prevent water from entering therein. The slightly higher pressure within the case 10 also assists in preventing water entry, as noted further above. The latching means used to secure the hatch 30 tightly to the case 10 may comprise an over-center type latch 44 disposed at the end of each of the side panels 18 and 20 adjacent the open end of the case 10, and cooperating catches 46 disposed upon the opposite ends of the hatch 30, or some other means of tightly securing the hatch 30 to the case 10 or 110, e.g., threaded hold-down bolts, etc.

As shown in FIGS. 1-3, the case 10, 110 may also include a push button control assembly gland 35 extending through the housing 12 with a push button control rod or other push button assembly that will align with and operate an on/off power switch on the computer C so that the diver can power the electronic device on or off without removing the electronic device from the case.

The pressurized waterproof case 10 or 110 is used by initially removing the hatch 30 from the remainder of the case, activating the computer C and setting any mechanical controls necessary, then placing the computer C within the case 10 or 110, and securing the hatch 30 in place. The air or other gas supply is then connected to the case 10 or 110, if not previously accomplished. The diver may then open the regulator slightly, e.g., regulator 34 for the case 10 of FIGS. 1 and 2, and begin the dive. The diver may periodically adjust the regulator 34 as he or she descends in order to maintain a slightly greater pressure within the case 10 or 110 than the pressure at the corresponding depth. Alternatively, the diver may elect to keep the regulator 34 closed until reaching the desired depth, and open the regulator upon reaching the working depth in order to pressurize the case 110 slightly above the ambient pressure developed by the water at the working depth. It is recognized that the diver may ascend and/or descend to some degree during the dive, and the diver may adjust the pressure within the case 10 manually as needed in order to prevent the flexible transparent touch-screen operation panel 28 from bearing against the touch screen of the computer C contained within the case 10 or 110. Even the relatively small gas cartridge 32 of the case 10 embodiment of FIGS. 1 and 2 provides sufficient gas for the duration of the dive, as the case 10 is sealed unless pressure therein exceeds external pressure to some predetermined degree. When the pressure is properly adjusted at a constant level, the relief valve 36 is closed and the pressure within the sealed case 10 is constant with no additional gas being required to maintain the pressure. When the diver ascends, the relief valve 36 vents excessive pressure from the case 10 or 110, requiring no further operation on the part of the diver. Pressure will remain slightly above ambient within the case 10 or 110 even as the diver surfaces. The diver may then open the latches 44 and remove the hatch 30 of the case 10 or 110 to retrieve the computer C from the case, and download or otherwise work conventionally with the data entered into the computer C during the dive.

The flexible membrane or panel 28 may be made from vinyl or other transparent, flexible material. The case 10, 110 preferably is substantially fluid-tight, i.e., water cannot leak in, and the pressurized gas (carbon dioxide, air, oxygen, an inert gas, etc.) cannot leak out.

It is contemplated that the pressurized waterproof case may be provided as a dedicated device in combination with a tablet computer or the like for use underwater. In that situation, the tablet computer C may be permanently sealed inside the case 10, 110, which would no longer require the hatch 30. The case 10, 110 may be equipped with a regulator valve 34 adapted for connection to a source of pressurized gas, and with a relief valve 36 to release gas when the pressure inside the case 10, 110 exceeds ambient pressure by too much. The tablet computer C may be connected to fittings or connectors mounted in the rigid walls of the case 10, 110, e.g., a power adapter for charging the battery, a USB port, etc., the fittings or connectors being equipped with appropriate waterproof or fluid-tight seals.

It is to be understood that the present invention is not limited to the embodiments described above, but encompasses any and all embodiments within the scope of the following claims.

I claim:

1. A pressurized waterproof case for an electronic device, comprising:
a housing defining a rigid container having an open front face and an access opening;
a flexible touch screen panel disposed over the front face;
a rigid hatch selectively disposed over the access opening, the rigid hatch, the touch screen panel, and the housing defining a substantially waterproof and fluid-tight case when the rigid hatch is disposed over the access opening, the substantially waterproof and fluid-tight case being dimensioned and configured for enclosing an electronic device having a touch screen user interface with the touch screen disposed beneath the touch screen panel;
a regulator valve mounted in the housing, the regulator valve being selectively openable to admit pressurized gas into the container to space the touch screen panel from the touch screen; and
a pressure relief valve mounted in the housing, the pressure relief valve being configured to release pressured gas from the container when pressure inside the container exceeds ambient pressure.

2. The pressurized waterproof case according to claim 1, further comprising at least one latch selectively securing said hatch to the container over the access opening.

3. The pressurized waterproof case according to claim 1, further comprising at least one seal disposed between said hatch and said container to form a substantially waterproof and fluid-tight seal around the access opening,

4. The pressurized waterproof case according to claim 1, wherein said touch screen panel is formed from transparent vinyl.

5. The pressurized waterproof case according to claim 1, further comprising a cartridge of compressed gas attached to said housing external to the container, the cartridge being connected to the regulator valve.

6. The pressurized waterproof case according to claim 5, further comprising a source of pressurized gas remotely disposed from the container, the source of pressurized gas being selectively attachable to the regulator valve.

7. The pressurized waterproof case according to claim 1, wherein said housing comprises a plurality of rigid plastic panels attached to each other by material forming a substantially waterproof and fluid-tight seal.

8. A pressurized waterproof case for an electronic device, comprising:
a housing defining a rigid container having an open front face and an access opening;
a flexible touch screen panel disposed over the front face;
a rigid hatch selectively disposed over the access opening, the rigid hatch, the touch screen panel, and the housing defining a substantially waterproof and fluid-tight case when the rigid hatch is disposed over the access opening, the substantially waterproof and fluid-tight case being dimensioned and configured for enclosing an electronic device having a touch screen user interface with the touch screen disposed beneath the touch screen panel;
a regulator valve mounted in the housing, the regulator valve being selectively openable to admit pressurized gas into the container to space the touch screen panel from the touch screen;
a cartridge of compressed gas attached to the housing external to the container, the cartridge being connected to the regulator valve; and
a pressure relief valve mounted in the housing, the pressure relief valve being configured to release pressured gas from the container when pressure inside the container exceeds ambient pressure.

9. The pressurized waterproof case according to claim 8, further comprising at least one latch selectively securing said hatch to the container over the access opening.

10. The pressurized waterproof case according to claim 8, further comprising at least one seal disposed between said hatch and said container to form a substantially waterproof and fluid-tight seal around the access opening.

11. The pressurized waterproof case according to claim 8, wherein said touch screen panel is formed from transparent vinyl.

12. The pressurized waterproof case according to claim 8, wherein said housing comprises a plurality of rigid plastic panels attached to each other by material forming a substantially waterproof and fluid-tight seal.

13. A method of using a tablet computer underwater using the pressurized waterproof case of claim 8, comprising the steps of:
removing the hatch from the access opening of the container of claim 8;
inserting the tablet computer into the container through the access opening, the tablet computer having a touch screen, the touch screen being aligned with the touch screen panel;
securing the hatch over the access opening;
diving underwater while carrying the housing;
opening the regulator valve to admit gas from the cartridge into the container to keep the touch screen panel spaced from the touch screen as water pressure increases with the depth of the dive; and
pressing against the touch screen panel to enter information into the tablet computer using the touch screen.

14. The method of using a tablet computer underwater according to claim 13, further comprising the step of releasing pressurized gas from the container through the pressure relief valve as pressure decreases while rising back to the surface of the water.

15. A pressurized waterproof case and a touch-screen electronic device for use therein, comprising in combination:
a housing defining a rigid container having an open front face;
a flexible touch screen panel disposed over the front face, the housing and the touch screen panel defining a substantially waterproof and fluid-tight enclosure;
an electronic device having a touch screen, the electronic device being disposed in the enclosure with the touch screen aligned with the touch screen panel; and
pressurized gas disposed in the enclosure, the gas having a pressure slightly greater than ambient pressure in order to space the touch screen panel from the touch screen, the touch screen panel being compressible against the touch screen when pressed by a user's finger.

16. The pressurized waterproof case for an electronic device and touch-screen electronic device combination according to claim 15, wherein said rigid container defined an access opening, the combination further comprising a hatch removably disposed over the access opening.

17. The pressurized waterproof case for an electronic device and touch-screen electronic device combination according to claim 15, further comprising a regulator valve mounted in the housing, the regulator valve being selectively openable to admit pressurized gas into the container to space the touch screen panel from the touch screen.

18. The pressurized waterproof case for an electronic device and touch-screen electronic device combination according to claim 17, further comprising a pressure relief valve mounted in the housing, the pressure relief valve being configured to release pressured gas from the container when pressure inside the container exceeds ambient pressure.

19. The pressurized waterproof case for an electronic device and touch-screen electronic device combination according to claim 17, further comprising a cartridge of compressed gas attached to the housing external to the container, the cartridge being connected to the regulator valve.

20. The pressurized waterproof case for an electronic device and touch-screen electronic device combination according to claim 17, wherein said touch screen panel is formed from transparent vinyl.
